(19) United States
(12) Patent Application Publication
(10) Pub. No.: US 2008/0049608 A1
(43) Pub. Date: Feb. 28, 2008

(54) Process for Securing Communication Connections and Associated Billing in a Redundant Communication Network

(76) Inventor: Klaus Hoffmann, Munchen (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 11/791,692

(22) PCT Filed: Oct. 12, 2005
(86) PCT No.: PCT/EP05/55187

§ 371 Date: May 24, 2007

(30) Foreign Application Priority Data
Nov. 25, 2004 (DE) 10 2004 056 983.5

(51) Int. Cl. G01R 31/08

(52) U.S. Cl. 370/217

(57) ABSTRACT

In a process for securing communication connections and associated billing in a communication network with a redundant structure, terminals communicate via brokers preferably an IP bearer, by means of messages, the correct operation of the terminals and/or hardware units being monitored by a monitoring function and the physical functions of broken down hardware units being taken over when one or more hardware units break down. After the physical functions are taken over, the operative hardware units transmit a message to the terminals involved and, in addition, ensure that the monitoring function is carried out by the still operative hardware units.

### CROSS REFERENCE TO RELATED APPLICATIONS

This application is the US National Stage of International Application No. PCT/EP2005/055187, filed Oct. 12, 2005 and claims the benefit thereof. The International Application claims the benefits of German application No. 102004056983.5 DE filed Nov. 25, 2004, both of the applications are incorporated by reference herein in their entirety.

### FIELD OF INVENTION

The invention relates to a process for securing communication connections and to the associated billing in a redundantly-structured communication network, in which terminals communicate with each other via bearers, preferably an IP bearer, by means of messages, with the correct function of the terminals and/or the hardware units being monitored by a monitoring unit and, on failure of one or more hardware units, the hardware units that are still operable taking over the physical functions of the failed hardware units.

### BACKGROUND OF INVENTION

The introduction of MGC-MGC communication (=Media Gateway Communication (=MGC) with the application of useful bearer technology, such as the Internet Protocol (=IP), means that the communication or payload channel respectively are switched through for communication. MGC-MGC communication is employed in situations in which a cleardown or a disconnection of connection setup, medium setup or bearer setup are undertaken respectively, i.e. in the case of a cleardown or a disconnection between communication terminal and (data) bearer. At present a number of standardized methods are used which, in the case of a cleardown or a disconnection of the connection setup, attempt to maintain the services in the telecommunications network.

At present for example there is ITU-T Standard (=International Telecommunication Union-Telecommunication Standardization Sector) Q.1902.x Bearer Independent Call Control Capability Set 2 (=BICC CS2) with its own indicator function (=Service Indicator) for message transfer (=Message Transfer Part;=MTP). In this case Q765.5 Bearer Application Transport (=BAT) describes for IP Bearer RTP (=Real Time Transport Protocol) as bearer technology, how it is possible, during disconnection of a call and of the bearer, to provide the end customer with their familiar services in the telecommunication network.

In the interim RFC 3261 (=Session Initiation Protocol=SIP) and RFC 3204 (ISUP MIME Type) have emerged as standards which allow the tunnel transport of ISUP: (=ISDN User Part) messages in the Session Initiation Protocol messages at the IETF (=Internet Engineering Task Force).

As an additional standard RFC 2976 (INFO Method) has been approved, which allows ISUP messages to be transported which could not be mapped onto the messages defined in RFC 2543 or RFC 3261.

With increasing acceptance of the NGN (=Next Generation Network) architecture the solutions relating to the security of the availability of the associated network devices for securing the communication services and in respect of the provision of secure billing data even on hardware failures are becoming ever more important. The network operators in particular expect the previously known functionalities to be secured even in the event of hardware failures of highly-centralized hardware devices which provide the signaling protocols between a number of MGCs and corresponding terminals.

### SUMMARY OF INVENTION

The Session Initiation Protocol in RFC3261 in particular imposes increased requirements on the security of a call so that data relevant for the call which is negotiated there by default dynamically on call setup and has to be restored accordingly on failure is not lost for this call. Simultaneously however there continues to be the requirement for it to be insured in this case too that the call itself and the billing are not interrupted and can also be passed on correctly.

Currently in communication systems, for example the applicant's hiE9200, provided no failure has occurred, the distant end is monitored in the Session Initiation Protocol based on the Session Timer Draft, with the aid of a monitoring function, for example through re-INVITE with the Session Description Protocol, in order to stop the connection and the billing if necessary if the distant end has failed.

The SDP (=Session Description Protocol) includes in this case the precise description of the characteristics of the currently used RTP bearer, for example the IP address, the RTP port, the CODECs used, also referred to as payload types, the state of the echo canceller, the through-connection state of the bearer, the SDP version counter and more besides.

For the two network units involved, such as terminal and data bearer, this requires especially that they must also restore this Session Description Protocol data additionally for a hardware failure for full support on the standby hardware. The preventive provision of memory space and additional computing capacity/time or processor time respectively for securing and restoring this data on the standby hardware is especially needed in order to fully support the currently implemented procedure. If this industry standard (SIP session timer procedure) is not taken into account after a hardware failure, a stable call would be unnecessarily cleared down if the corresponding call data could not be fully restored. A stable call is a call, which, through the telephone handset being lifted, reaches the state: “subscriber has answered” and no further feature is activated, such as call hold for example. The cleardown of a stable call results from the fact that the SDP data or also other call data has been lost and an answer can no longer be provided to SIP session timer re-INVITE. Since especially the Session Description Protocol in the Session Initiation Protocol is used for control of functions, such as Call Hold, Bearer Redirection, CODEC switchover of the bearer, this means the unnecessary provision of memory and computing capacity for a stable call that does not really need this memory and computing capacity.

An object of the invention is thus to make available a method for securing the communication connections and the associated billing in a communication network, preferably in an SIP communication network, which in the event of a hardware failure provides the familiar communication services, but which, by contrast with the previously known standardized securing methods, is able to be executed far more simply and with significantly lower memory and computing capacity.

This object is achieved by the features of the independent claims. Advantageous developments of the invention are the object of dependent claims.

The inventor has recognized that with Standard RFC3261 with the Session Initiation Protocol and with RFC3264 with the Session Description Protocol offer/answer and the SIP session draft (=Session Timers in the Session Initiation Protocol=draftietf-sip-session-timer-13), the option of monitoring the SIP distant end is available. In Chapter 7.4 of: “Generating Subsequent Session Refresh Requests of the SIP session draft” the use of the UPDATE method is made possible for RFC3311 without using the Session Description Protocol (SDP:RFC2327). The contents of (=Session Timers in the Session Initiation Protocol=draftietf-sip-session-timer-15), being fully incorporated into this application.

Accordingly the inventor proposes improving the known process for securing the communication connections and the associated billing in a redundantly-structured communication network in which terminals communicate via bearers, preferably an IP bearer, by means of messages, with the correct function of the terminals and/or of the hardware units being monitored by a monitoring function and, on failure of one or more hardware units, the still operable hardware units taking over the physical functions of the failed hardware units. in such a way that, immediately after the taking over the physical functions, the operable hardware units transmit a message to the terminals involved and additionally establish that the monitoring function will be executed by the still operable hardware units.

The result of this is that, if one or more hardware units fail, the existing communication connections or those to be set up again and the associated billing in a communication network, preferably an SIP communication network, continue to function correctly and the familiar communication services remain available to the communication user.

The redundantly-structured communication network concerned can be an SIP communication network and the messages transferred can be SIP messages

The previously required restoration of the call data involved in the event of a (hardware) failure, for example via the Session Description Protocol, with the concomitant necessary use of memory and computing capacity can be avoided by using the new method.

It is of advantage for the process for the terminals receiving a message from the operable hardware units to send a message back to these units. For example the SIP terminal involved can send a 200 OK as an answer to the UPDATE. This provides a simple method of establishing whether the existing communication connection is actually affected by the failure of the hardware unit.

Furthermore it is advantageous for the terminals and/or the hardware units to be monitored by an SIP session timer (session timer in the Session Initiation Protocol). This gives the SIP system a simple method of monitoring the SIP communication devices involved.

The SIP session timer monitoring function can establish whether the terminals or the hardware components involved are transmitting or receiving an INVITE or UPDATE message, with the UPDATE message being used without SDP. The role of the SIP end point is determined in this way. This is especially advantageous since it means that the distant end no longer has to transmit a re-INVITE with the Session Description Protocol, which then by default in its turn would have to be answered with the no longer necessarily present Session Description Protocol with all its aspects in the answer to re-INVITE. The effort of establishing the connection between the new hardware unit and the previous terminal, after the takeover of the functions of the failed hardware units is thus kept lower than previously in the new process.

In one version of the process the billing is executed by an SIP proxy, preferably a proxy server. If the SIP proxy fails the message UPDATE can be sent to both communicating terminals for security reasons after the takeover of the physical functions by the operable hardware units, so that the call is not cleared down. In which case the side waiting to receive the periodic re-INVITE/UPDATE, clears down the call if the message was received.

In the new process the billing can continue to be executed depending on the answer of the terminals, or stopped if no answer comes from the terminals. If for example a message of an operable hardware unit to the terminal involved is answered with a negative answer, it can be deduced from this that this side is still capable of functioning and the call and the billing can continue.

The invention is explained in greater detail below with reference to the preferred exemplary embodiment with the aid of the figures, in which case it is pointed out that only the major elements of importance for the direct understanding of the invention are shown. In this case the following reference symbols are used: 1: SIP communication network; 2: IP bearer; 3: Private Branch Exchange/hiG1000; 4: TX (=Transit Exchange); 5: LE (=Local Exchange); 6: PSTN (=Public Switched Telephone Network); 7.1-7.x: Communication terminal/telephone; 8: Media node/hiQ9200; 9: CMN Call Mediation Node from BICC ITU-T Q.1901; 10: SIP Proxy; 11: SIP terminal; 12: Computer; 13: Transfer of SIP messages; 14: First hardware unit; 14.1: Failure of the first hardware unit; 15: Second hardware unit; 16: Redundant connection of first and second hardware unit; 17: Message/UPDATE; 18: Answer to message UPDATE/200 OK.

### BRIEF DESCRIPTION OF THE DRAWINGS

In detail the figures show:

FIG. 1: schematic structure of an SIP communication network;

FIG. 2: basic sketch showing the failure of a hardware unit and explaining the subsequent steps in the new process.

### DETAILED DESCRIPTION OF INVENTION

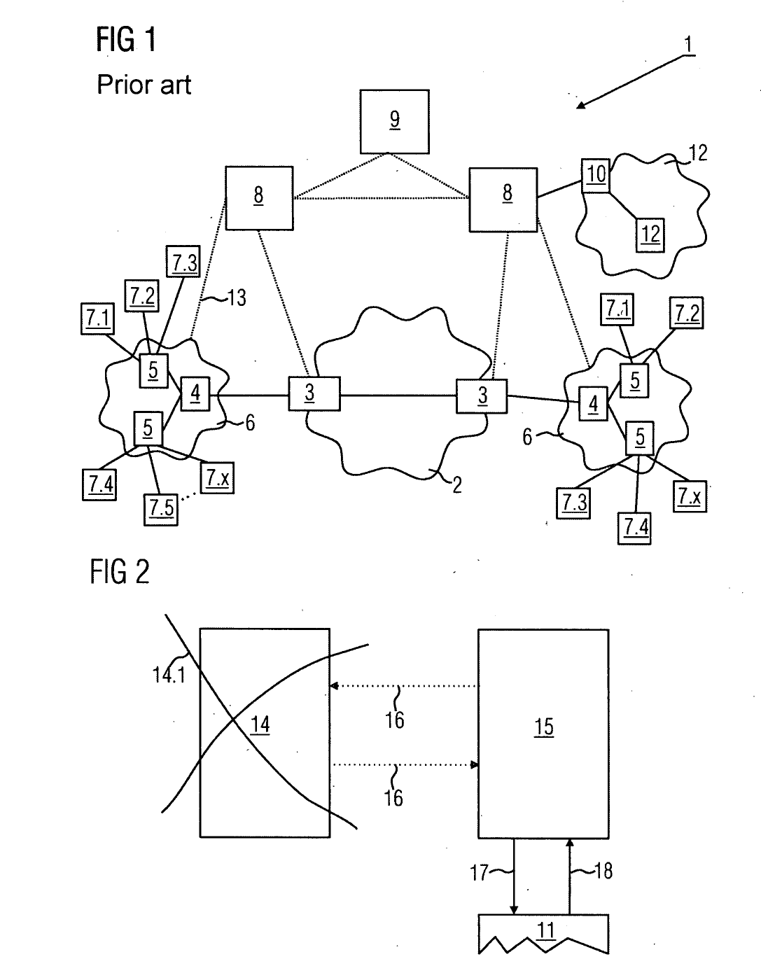

FIG. 1 shows a schematic structure of an SIP communication network 1. In this SIP communication network 1 communication terminals 7.1-7.x, preferably simple telephones, are connected to each other via a bearer, here an IP bearer 2. The communication terminals 7.1-7.x are connected to Public Switched Telephone Networks 6. Computers 12 can however also communicate with each other via this SIP communication network 1 and the transfer of SIP messages 13 taking place within it. The inventive idea thus also covers networks in which SIP terminals are connected directly to an SIP proxy in a pure SIP domain, without a PSTN 6.

The network operator would also like to ensure, on failure of one or more hardware units of the SIP communication network 1, that on the one hand the billing for the existing communication connections is being correctly accounted and can continue. On the other hand the familiar services should be available to users of the SIP communication network 1 without them having to wait despite the failure. To this end a new simple process is presented, which makes it possible to secure the data connections and the associated billing data in an SIP communication network.

FIG. 2 shows a basic diagram in which a failure 14.1 of a hardware unit, here the first hardware unit 14, is depicted. The failure 14.1 of the first hardware unit is depicted by the X symbol FIG. 2 also depicts schematically how the second hardware unit 15 takes over the functions of the failed first hardware unit 14 and which steps are initiated in the new process for this purpose.

In a communication network for security reasons the hardware units 14 and 15 have a redundant connection 16 between them, so that it is possible for the function of the failed hardware unit 14 to be taken over by the still operable hardware unit 15.

Methods and processes for detecting hardware failures and the further handling of hardware failures or the associated transfer of relevant data to the standby hardware unit respectively are already known from the prior art. The relevant parts of the Session Initiation Protocol (=SIP) are preferably used in the new process.

On failure 14.1 of the first hardware units 14 in accordance with the redundant configuration of the communication network, the second hardware unit 15 will take over the function of the first hardware unit 14. Previously the first hardware unit 14 was connected to an SIP terminal 11, for example a telephone and/or a computer. The connection of the first hardware unit 14 to the SIP terminal 11 is not shown in FIG. 2. After failure 14.1 of the first hardware unit 14, the second hardware unit 15 will be connected to the SIP terminal 11 and will communicate with the latter.

After the physical function(s) of the first hardware unit 14 has (have) been taken over, the second hardware unit 15 sends a message 17 in the new process to the SIP terminal 11, here an SIP UPDATE. SIP UPDATE is an SIP message or a possible method respectively which is defined in RFC3311 and is not excluded in the SIP session timer draft, which can indicate a change to the SIP call, without using the Session Description Protocol of the communication network to do so. The message 17 can contain the additional definition that the SIP Session Timer monitoring function is to be executed immediately from here on, that is by the second hardware unit 15.

The SIP Session Timer monitoring function can define which of the two parties, i.e. the second hardware unit 15 or the SIP terminal 11, is to transmit the messages 11 INVITE or UPDATE, for establishing the readiness or the absence of the distant end. The message INVITE is on the one hand an SIP message which can establish a connection or on the other hand it makes it possible for an existing stable connection as re-INVITE to change the call data. It can also be used for the SIP session timer procedure.

Establishing that the second hardware unit 15 will be the new communication partner of the SIP terminal 11 can now also be undertaken, independently of the previous history on the first hardware unit 14, by the second hardware unit 15. This is especially advantageous, since the distant end can now no longer send a re-INVITE with the Session Description Protocol, which then by default in its turn would have to be answered by the no longer necessarily available Session Description Protocol with all its aspects in the answer 18, here a 200 OK for re-INVITE.

In accordance with the invention the SIP partner 11, which receives the message 17, here an UPDATE, responds with an answer 18, here a 200 OK. This is the default positive SIP answer according to RFC3261 to a SIP message, here a positive answer to UPDATE. This means that both units, the second hardware unit 15 and the SIP terminal 11, know that the call or the connection is in order and the billing and the call do not need to be ended. This is especially therefore the case, since despite failure 14.1 of first hardware unit 14, which only provides the SIP signaling, the associated communication network is still very capable of functioning and the communication users are still speaking to each other or can communicate respectively, and the failure 14.1 of the first hardware unit 15 has no effects.

If the distant end answers the message/UPDATE 17 contrary to expectations with a negative answer 18, the second hardware unit 2 will/can evaluate this reaction as a confirmation, according to which the distant end is still capable of functioning, and the call and the billing can continue.

In the case of an SIP proxy failure, which for example undertakes the billing, in accordance with the invention, the UPDATE message is then to be sent to both sides of the connection.

Naturally the features of the invention given in this document cannot only be used in the combination specified but also in other combinations or on their own, without departing from the framework of the invention.

The following abbreviations have been used:
BAT Bearer Application Transport
BICC Bearer Independent Call Control
CMN Call Mediation Node
CODEC Coding Decoding
IETF Internet Engineering Task Force
IP Internet Protocol
ISDN Integrated Services Digital Network
ISUP ISDN User Part
ITU-T International Telecommunication Union-Telecommunication Standardization Sector
LE Local Exchange
MG Media Getaway
MGC Media Getaway Communication
MTP Message Transfer Protocol
NGN Next Generation Network
PSTN Public Switched telephone Network
RFC Request For Comments
RTP Real Time Transport Protocol
SIP Session Initiation Protocol
SDP Session Description Protocol
TX Transit Exchange

1.-7. (canceled)

8. A method for securing the communication connections and the associated billing in a redundantly-structured communication network, in which terminals communicate using messages via an IP bearer, with a monitoring function being used to monitor the correct function of the terminals and/or the hardware units, comprising:
taking over physical functions of a failed hardware unit by an operable hardware unit in response to a failure of the failed hardware unit;
transferring, by the operable hardware after taking over the physical functions unit, a message to a terminal partnered with the failed hardware unit, thereby establishing the operable hardware as the communication partner of the terminal; and
establishing that the monitoring function will be executed by the operable hardware unit.

9. The method as claimed in the claim 8, wherein a SIP communication network is used as the redundantly-structured communication network and the transmitted messages are SIP.

10. The method as claimed in the claim 8, further comprising receiving a response message from the terminal in response to the transferred message.

11. The method as claimed in the claim 8, wherein the terminal and the hardware unit are monitored by an SIP session timer.

12. The method as claimed in the claim 11, wherein the SIP session timer monitoring function establishes whether the terminal or the operable hardware unit is transmitting or receiving an INVITE or UPDATE message, with the UPDATE message being used without SDP.

13. The method as claimed in the claim 8, wherein the terminal or the hardware unit is monitored by an SIP session timer.

14. The method as claimed in the claim 13, wherein the SIP session timer monitoring function establishes whether the terminal or the operable hardware unit is transmitting or receiving an INVITE or UPDATE message, with the UPDATE message being used without SDP.

15. The method as claimed in the claim 8, wherein the billing is undertaken by a SIP proxy and on a failure of the SIP proxy, the message is sent to both sides of the connection.

16. The method as claimed in the claim 8, wherein the billing continues when a response is received from the terminal, wherein the billing ends and the call terminates when no response is received from the terminal.

17. The method as claimed in the claim 16, wherein response is an acknowledgement or a negative acknowledgement.

18. A method for securing the communication connections and the associated billing in a redundantly-structured communication network, in which terminals communicate using messages via an IP bearer, with a monitoring function being used to monitor the correct function of the terminals and/or the hardware units, comprising:
taking over physical functions of a failed hardware unit by an operable hardware unit in response to a failure of the failed hardware unit;
transferring, by the operable hardware after taking over the physical functions unit, a SIP UPDATE message without a SDP to a terminal partnered with the failed hardware unit, thereby establishing the operable hardware as the communication partner of the terminal, and
receiving a response message from the terminal in response to the transferred message,
wherein a SIP communication network is used as the redundantly-structured communication network and the transmitted messages are SIP, and
wherein the connection is maintained after the failure of the failed hardware unit.

19. The method as claimed in the claim 18, wherein based on a SIP session timer monitoring function the terminal or the operable hardware unit transmits a further message to establish a readiness of a device at a distant end of the connection.

20. The method as claimed in the claim 19, wherein the further message is an UPDATE.

21. The method as claimed in the claim 19, wherein the further message is an INVITE OR re-INVITE.

22. The method as claimed in the claim 18, wherein the billing continues in response to the response message.

23. The method as claimed in the claim 22, wherein response is an acknowledgement.

24. The method as claimed in the claim 22, wherein response is a negative acknowledgement.
